(19) United States
(12) Patent Application Publication
(10) Pub. No.: US 2015/0136759 A1
(43) Pub. Date: May 21, 2015

(54) MICROWAVE HEATING APPARATUS

(71) Applicant: Tokyo Electron Limited, Tokyo (JP)

(72) Inventors: Taro IKEDA, Yamanashi (JP); Sumi TANAKA, Yamanashi (JP)

(21) Appl. No.: 14/541,010

(22) Filed: Nov. 13, 2014

(30) Foreign Application Priority Data
Nov. 15, 2013 (JP) 2013-236717

(51) Int. Cl. H05B 6/70; H01L 21/67; H05B 6/64

(52) U.S. Cl. CPC H05B 6/707; H05B 6/6411; H01L 21/67115
USPC 219/690; 219/754

(57) ABSTRACT

A microwave heating apparatus includes a processing chamber configured to accommodate a substrate; a substrate holding unit configured to hold and rotate the substrate in the processing chamber; a microwave generating source configured to generate a microwave; and a plurality of microwave inlet ports formed at a surface of the processing chamber which faces the substrate in the processing chamber, each of the microwave inlet ports having an opening area that gradually becomes wider toward the substrate. The microwave generated by the microwave generating source is irradiated to the substrate in the processing chamber through the microwave inlet ports to heat the substrate.

### CROSS-REFERENCE TO RELATED APPLICATIONS

This application claims priority to Japanese Patent Application No. 2013-236717 filed on Nov. 15, 2013, the entire contents of which are incorporated herein by reference.

### FIELD OF THE INVENTION

The present invention relates to a microwave heating apparatus for heating a substrate by introducing a microwave into a processing chamber.

### BACKGROUND OF THE INVENTION

In a semiconductor device manufacturing process, various processes such as film formation, modification, heat treatment and the like are sequentially performed on a semiconductor wafer (hereinafter, referred to as “wafer”). An example of the heat treatment for the wafer is an annealing process for implanting ions as impurities into a silicon substrate, restoring crystal defects caused by the ion implantation, and forming a diffusion layer on a surface layer of the silicon substrate, e.g., a wafer.

Recently, along with the trend toward miniaturization of semiconductor devices, it is required to form a thin diffusion layer having a small depth in a thickness direction of the wafer. To do so, heat treatment using a microwave is suggested in, e.g., Japanese Patent Application Publication No. 2013-152919. Referring to Japanese Patent Application Publication No. 2013-152919, an object is heated by irradiating a microwave transmitted through a rectangular waveguide into a processing chamber through a plurality of rectangular inlet ports formed at a ceiling portion of the processing chamber. In the heat treatment using a microwave, the microwave directly acts on a polarization point generated at a crystal lattice defect portion or ions as impurities, so that the impurities are activated at a low temperature and this suppresses expansion of the diffusion layer. Further, effective heat treatment can be realized due to Joule loss caused by high-speed vibration of thermal electrons eluted on a surface at a high temperature.

Meanwhile, in the above annealing process, the surface of the wafer needs to be uniformly heated to improve in-plane processing uniformity of the wafer. However, the microwave irradiated from, e.g., the rectangular inlet ports has strong directivity in a perpendicular direction to the long side of the rectangle (electric field surface). Therefore, it is difficult to irradiate the microwave at a desired intensity to a desired location on the substrate. Accordingly, it is difficult to uniformly irradiate the microwave to the substrate in the processing chamber. As a result, the temperature distribution in the surface of the wafer becomes non-uniform.

To this end, a technique for uniformly heating the wafer by adjusting the shape or the arrangement of the rectangular inlet ports is disclosed in Japanese Patent Application Publication No. 2013-152919. Since, however, it is still difficult to irradiate the microwave at a desired intensity to a desired location, there is a limit in achieving the uniformity of the heat treatment. Meanwhile, the uniformity improvement of the heat treatment is further required to meet the recent demand for the miniaturization of semiconductor devices.

### SUMMARY OF THE INVENTION

n view of the above, the present invention provides a microwave heating apparatus capable of uniformly heating a surface of a substrate when the substrate is heated by introducing a microwave into a processing chamber.

In accordance with an aspect of the present invention, there is provided a microwave heating apparatus, including: a processing chamber configured to accommodate a substrate; a substrate holding unit configured to hold and rotate the substrate in the processing chamber; a microwave generating source configured to generate a microwave; and a plurality of microwave inlet ports formed at a surface of the processing chamber which faces the substrate in the processing chamber, each of the microwave inlet ports having an opening area that gradually becomes wider toward the substrate, wherein the microwave generated by the microwave generating source is irradiated to the substrate in the processing chamber through the microwave inlet ports to heat the substrate.

### BRIEF DESCRIPTION OF THE DRAWINGS

The objects and features of the present invention will become apparent from the following description of embodiments, given in conjunction with the accompanying drawings, in which:

FIG. 1 is a schematic vertical cross sectional view of a microwave heating apparatus in accordance with an embodiment of the present invention;

FIG. 2 is an explanatory view showing a schematic configuration of a microwave unit.

FIG. 3 is an explanatory view showing a schematic configuration of a power supply unit;

FIG. 4 is a vertical cross sectional view schematically showing a configuration of a microwave inlet port and the vicinity thereof.

FIG. 5 is a view showing a bottom surface of a ceiling plate of a processing chamber;

FIG. 6 is an explanatory view showing a shape of a transmission window;

FIG. 7 is an explanatory view of the case where a microwave has been irradiated from the microwave inlet port;

FIG. 8 is an explanatory view of the case where a microwave has been irradiated from the microwave inlet port;

FIGS. 9A to 9D are explanatory views showing intensity distribution of an electromagnetic field in the case where a microwave has been irradiated from microwave inlet ports of the microwave heating apparatus in accordance with the embodiment of the present invention; and

FIGS. 10A to 10D are explanatory views showing intensity distribution of an electromagnetic field in the case where a microwave has been irradiated in a conventional microwave heating apparatus.

### DETAILED DESCRIPTION OF THE EMBODIMENTS

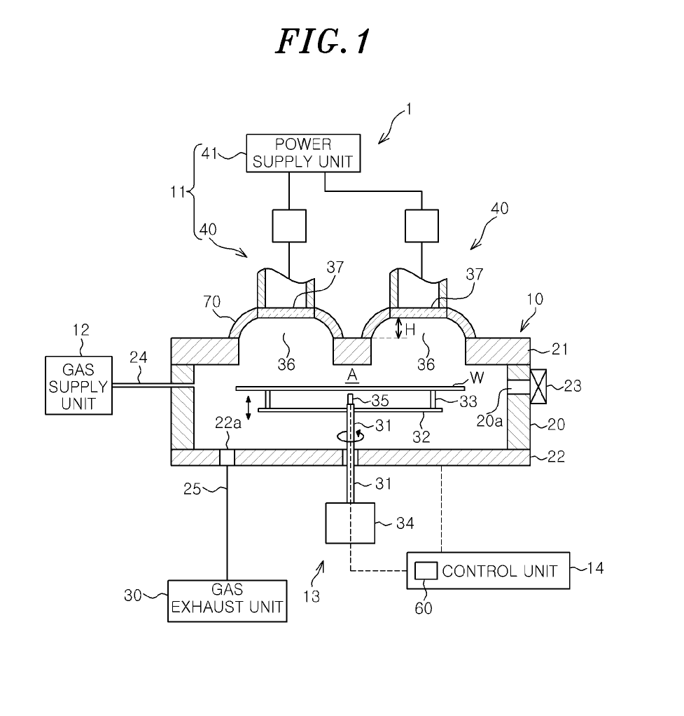

Hereinafter, an embodiment of the present invention will be described with reference to the accompanying drawings. Further, like reference numerals will be used for like parts having substantially the same functions throughout the specification and the drawings, and redundant description thereof will be omitted. FIG. 1 is a vertical cross sectional view schematically showing a microwave heating apparatus 1 of the present embodiment. In the present embodiment, the case of heating a semiconductor substrate, e.g., a wafer, by using a microwave heating apparatus 1 will be described as an example.

As shown in FIG. 1, the microwave heating apparatus 1 includes: a processing chamber 10 for accommodating a wafer W; a microwave generating source 11 for generating a microwave; a gas supply unit 12 for supplying a predetermined gas into the processing chamber 10; a wafer holding unit 13 for holding and rotating the wafer W in the processing chamber 10; and a control unit 14 for controlling the components of the microwave heating apparatus 1. The processing chamber 10 is made of metal, e.g., aluminum or the like.

The processing chamber 10 has, e.g., a substantially rectangular parallelepiped shape as a whole. The processing chamber 10 includes a sidewall 20 having a square column shape when seen from the top, a substantially square-shaped ceiling plate 21 which covers an upper end of the sidewall 20, and a substantially square-shaped bottom plate 22 which covers a lower end of the sidewall 20. A processing space A of the processing chamber 10 is formed at a region surrounded by the sidewall 20, the ceiling plate 21, and the bottom plate 22. Further, surfaces of the sidewall 20, the ceiling plate 21 and the bottom plate 22 which face the processing space A are subjected to mirror treatment and serve as reflection surfaces that reflect the microwave. Accordingly, compared to the case where those surfaces are not subjected to mirror treatment, the wafer W can reach a higher temperature during the heat treatment.

A loading/unloading port 20a for the wafer W is formed at the sidewall 20 of the processing chamber 10. A gate valve 23 is provided at the loading/unloading port 20a. The gate valve 23 can open/close the loading/unloading port 20a by using a driving unit (not shown). A seal member or a choke unit (both not shown) for preventing leakage of a microwave is provided between the gate valve 23 and the sidewall 20. A gas supply line 24 is connected to the sidewall 20 of the processing chamber 10. A gas from the gas supply unit 12 is supplied into the processing chamber 10 through the gas supply line 24. The gas supply unit 12 supplies a processing gas or a purge gas, e.g., nitrogen gas, argon gas, helium gas, neon gas, hydrogen gas or the like.

A gas exhaust port 22a is formed at the bottom plate 22 of the processing chamber 10. A gas exhaust unit 30, e.g., a vacuum pump or the like, is connected to the gas exhaust port 22a via a gas exhaust line 25.

The wafer holding unit 13 includes: a hollow tube-shaped shaft 31 vertically penetrating through the center of the bottom plate 22 and extending to the outside of the processing chamber 10; an arm 32, provided near the upper end of the shaft 31, extending in a horizontal direction; and supporting pins 33, provided at the upper end of the arm 32, for supporting the wafer W. A driving unit 34 for rotating and vertically moving the shaft 31 is connected to the lower end of the shaft 31. The position of the wafer W in the height direction in the processing chamber 10 is adjusted by vertically moving the supporting pins 33 that support the wafer W by using the driving unit 34. The driving unit 34 is provided, e.g., at the outside of the processing chamber 10. A seal member (not shown) airtightly seals the space between the shaft 31 and the bottom plate 22.

Further, a temperature measuring unit 35 for measuring a temperature of the wafer W is provided inside the shaft 31. As for the temperature measuring unit 35, a radiation thermometer is used, for example. The temperature measured by the temperature measuring unit 35 is inputted to the control unit 14 and used to control the microwave heating of the wafer W.

Microwave inlet ports 36 through which the microwave generated by the microwave generating source 11 is irradiated into the processing chamber 10 are formed at the ceiling plate 21 of the processing chamber 10. Transmission windows 37 are provided so as to cover the microwave inlet ports 36. The microwave generating source 11 is provided above the transmission windows 37. The microwave generating source 11 includes: microwave units 40 for generating a microwave and introducing the generated microwave into the processing chamber 10; and a power supply unit 41 connected to the microwave units 40. In the present embodiment, the microwave inlet ports 36 are formed at, e.g., four locations of the ceiling plate 21, and the microwave units 40 are respectively provided for the microwave inlet ports 36. In other words, the processing chamber 10 is provided with four microwave units 40. The power supply unit 41 is used in common for four microwave units 40. Otherwise, the power supply unit 41 may be separately provided for each microwave unit 40.

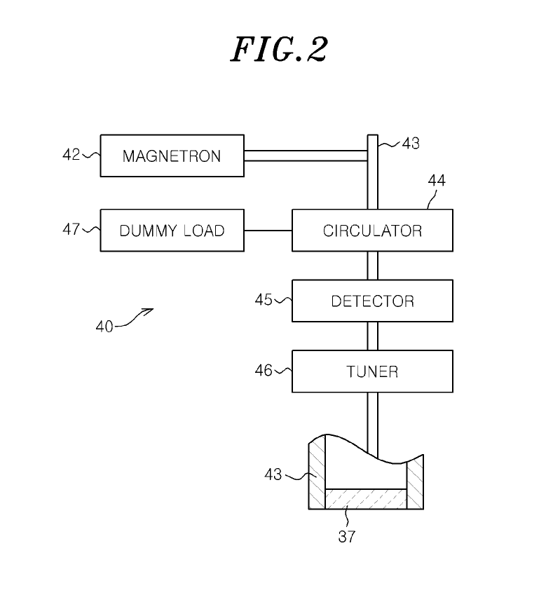

As shown in FIG. 2, for example, the microwave unit 40 includes: a magnetron 42 for generating a microwave; a waveguide 43 for transmitting the microwave; a circulator 44 provided between the waveguide 43 and the transmission window 37; a detector 45; a tuner 46; and a dummy load 47 connected to the circulator 44.

The magnetron 42 includes an anode and a cathode (both not shown) to which a high voltage from the power supply unit 41 is applied. As for the magnetron 42, one capable of oscillating microwaves of various frequencies may be used. The frequency of the microwave to be generated by the magnetron is optimally selected depending on the types of processing for the wafer W. For example, in the case of heat treatment, a microwave having a high frequency of, e.g., about 2.45 GHz or 5.8 GHz, among frequencies in the ISM band is used.

The waveguide 43 has a rectangular parallelepiped cross section and extends upward from the top surface of the transmission window 37 and the ceiling plate 21 of the processing chamber 10. The magnetron 42 is connected to the vicinity of the upper end portion of the waveguide 43. The microwave generated by the magnetron 42 is transmitted into the processing space A of the processing chamber 10 via the waveguide 43 and the transmission window 37.

The circulator 44, the detector 45 and the tuner 46 are provided in that order from the upper end portion toward the lower end portion of the waveguide 43. The circulator 44 and the dummy load 47 serve as an isolator for isolating the reflection wave of the microwave introduced into the processing chamber 10. In other words, the reflection wave from the processing chamber 10 is transmitted to the dummy load 47 by the circulator 44. The dummy load 47 converts the reflection wave transmitted by the circulator 44 into heat.

The detector 45 detects the reflection wave from the processing chamber 10 in the waveguide 43. The detector 45 includes, e.g., an impedance monitor, specifically, a standing wave monitor for detecting an electric field of a standing wave in the waveguide 43. Further, the detector 45 may include, e.g., a directional coupler, capable of detecting a travelling wave and a reflection wave.

The tuner 46 for controlling an impedance matches an impedance between the magnetron 42 and the processing chamber 10. The impedance matching of the tuner 46 is carried out based on the detection result of the reflection wave of the detector 45.

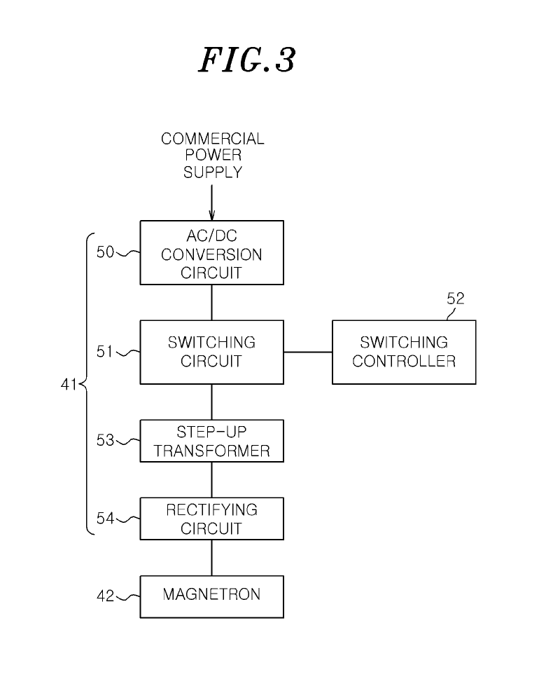

The power supply unit 41 applies a high voltage for generating a microwave to the magnetron 42. As shown in FIG. 3, for example, the power supply unit 41 includes: an AC/DC conversion circuit 50 connected to a commercial power supply; a switching circuit 51 connected to the AC/DC conversion circuit 50; a switching controller 52 for controlling an operation of the switching circuit 51; a step-up transformer 53 connected to the switching circuit 51; and a rectifying circuit 54 connected to the step-up transformer 53. The magnetron 42 and the step-up transformer 53 are connected to each other through the rectifying circuit 54.

The AC/DC conversion circuit 50 rectifies, e.g., three phase 200V AC voltage, supplied from the commercial power supply and converts it to a DC. The switching circuit 51 controls on/off of the DC converted by the AC/DC conversion circuit 50. In the switching circuit 51, the switching controller 52 performs PWM (pulse width modulation) or PAM (pulse amplitude modulation), thereby generating a pulsed voltage. The pulsed voltage outputted from the switching circuit 51 is boosted by the step-up transformer 53. The boosted pulsed voltage is rectified by the rectifying circuit 54 and supplied to the magnetron 42.

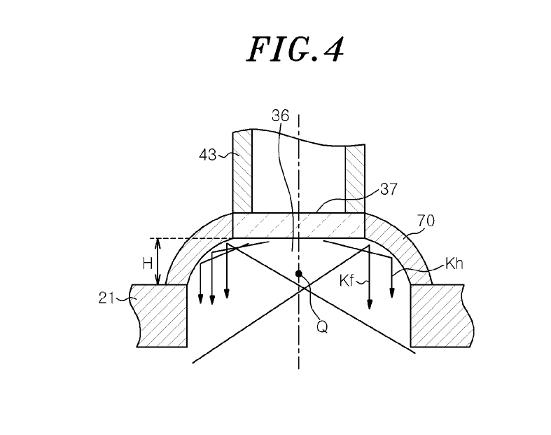

Hereinafter, the microwave inlet port 36 provided at the ceiling plate 21 will be described. As shown in FIG. 4, the vertical cross section of the microwave inlet port 36 has a parabolic shape that opens downward. In other words, the microwave inlet port 36 has a parabolic surface whose opening area gradually becomes wider toward the wafer W. The parabolic surface is formed by the bottom surface of the transmission window 37 and an annular member 70 whose opening area gradually becomes wider toward the bottom. The annular member 70 is made of, e.g., aluminum. The parabolic surface of the microwave inlet port 36 is set to have a predetermined height H. In the present embodiment, the height H is set to about 5 mm to 40 mm.

The shape of the parabolic surface of the microwave inlet port 36 is set such that a focus Q of the parabolic surface is located between the wafer W and the transmission window 37 (e.g., within a range of H+30 mm), and more preferably, as shown in FIG. 4, within a range of the height H of the microwave inlet port 36. Therefore, as shown in FIG. 4, a microwave Kh including a horizontal component among the microwave irradiated into the processing chamber 10 through the transmission window 37 is reflected on the inner surface of the annular member 70 of the microwave inlet port 36 and moved downward in a substantially vertical direction. Accordingly, the microwave Kh irradiated through the transmission window 37 can be prevented from entering the other microwave inlet ports 36. As a result, the loss caused when the microwave Kh enters the other microwave inlet ports 36 is reduced and the effective heat treatment using a microwave can be realized. Further, a microwave Kf that has been irradiated from the microwave inlet port 36 into the processing chamber 10, reflected on the surface of the wafer W, and then entered the same microwave inlet port 36 is also reflected on the inner surface of the annular member 70 and moved downward in a substantially vertical direction. Therefore, the microwave introduced into the processing chamber 10 from the microwave unit 40 through the transmission window 37 is intensively irradiated to a region that is substantially vertically below the microwave inlet ports 36.

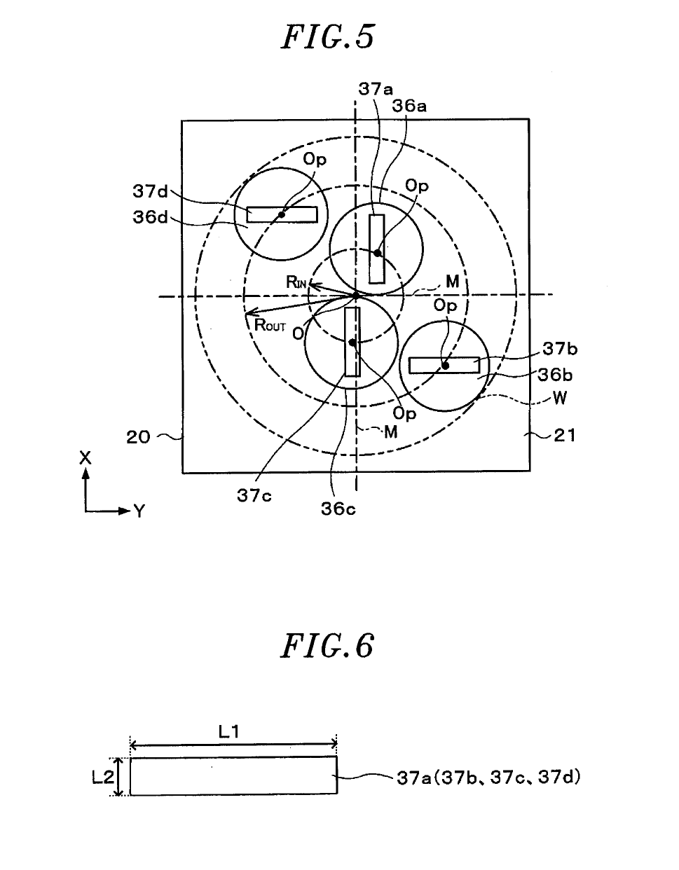

Next, the arrangement of the microwave inlet ports 36 will be described. FIG. 5 shows the ceiling plate 21 seen from the bottom. In FIG. 5, a notation O indicates the center of the wafer and the ceiling plate 21. A notation M indicates, in four sides that define a boundary between the ceiling plate 21 and the sidewall 20, lines connecting the middle points of the opposite sides. The center of the wafer W does not necessarily coincide with the center of the ceiling plate 21.

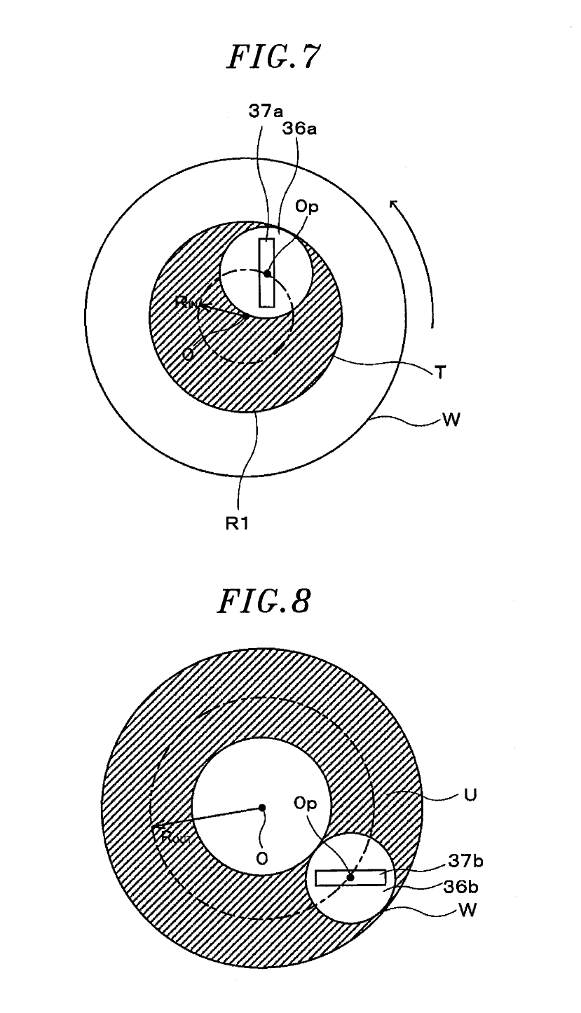

As shown in FIG. 5, e.g., four microwave inlet ports 36a to 36d are formed at the ceiling plate 21. As shown in FIGS. 5 and 6, transmission windows 37a to 37d that cover the microwave inlet ports 36a to 36d have a rectangular shape.

It is preferable that a length L1 of a long side of each of the transmission windows 37a to 37d and a wavelength λg in the waveguide 43 satisfy L1=n×λg/2 (n is a positive integer). The transmission windows 37a to 37d may have different sizes or different ratios of lengths L1 and L2. However, it is preferable that the transmission windows 37a to 37d have the same size and the same ratio of the lengths L1 and L2 in order to perform uniform heat treatment by uniformly irradiating the microwave to the wafer W.

In the present embodiment, in order to obtain uniform distribution of an electric field near the top surfaces of the wafer W, as shown in FIG. 5, the centers Op of the respective microwave inlet ports 36a to 36d overlap with either one of two concentric circles about the center O of the wafer W, the two concentric circles having a diameter smaller than the wafer W. At this time, not all the centers Op of the microwave inlet ports 36a to 36d are positioned on the same circumference. In the present embodiment, as shown in FIG. 5, for example, the centers Op of two microwave inlet ports 36a and 36c are positioned on a circumference having a radius R_{IN} and the centers Op of the other two microwave inlet ports 36b and 36d are positioned on a circumference having a radius R_{OUT} greater than the radius R_{IN}.

As shown in FIG. 5, long sides and short sides of the transmission windows 37a to 37d are in parallel to the inner surface of the sidewall 20. In FIG. 5, the long sides of two transmission windows 37a and 37c are in parallel to the sidewall in X direction and the long sides of the other two transmission windows 37b and 37d are in parallel to the sidewall 20 in Y direction.

The respective microwave inlet ports 36a to 36d are arranged so as not to interfere with one another and have diameters that allow paths of the microwave inlet ports 36a and 36c rotating along the circumference having the radius R_{IN} and the microwave inlet ports 36b and 36d rotating along the circumference having the radius R_{OUT} to cover the entire top surface of the wafer W. In other words, the outer peripheral portion of the wafer W is covered by the microwave inlet ports 36b and 36d positioned on the circumference having the radius R_{OUT} and the central portion of the wafer W is covered by the microwave inlet ports 36a and 36c positioned on the circumference having the radius R_{IN}. In the present embodiment, the microwave inlet ports 36a to 36d have the same diameter.

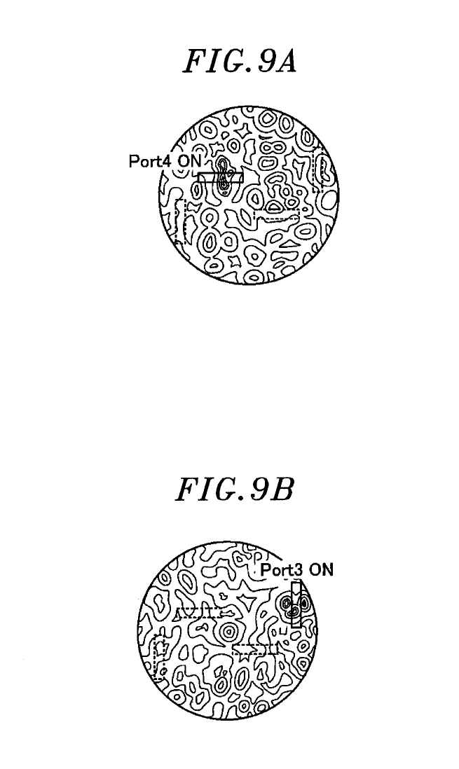

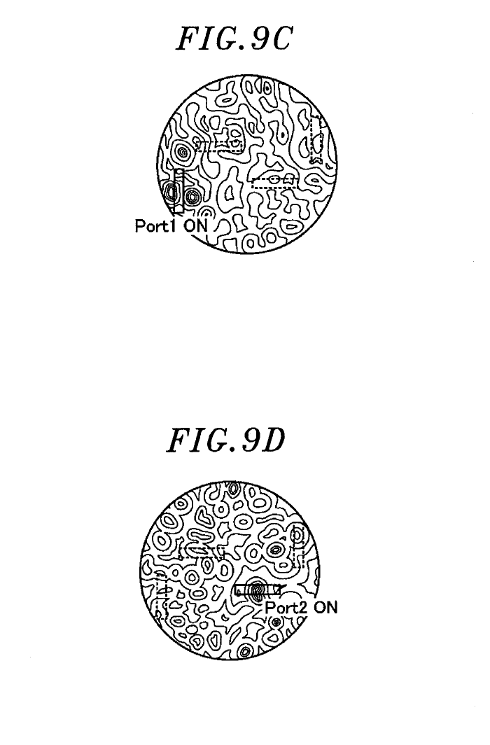

In this case, as shown in FIG. 7, if the wafer W is rotated by 360 degrees while irradiating the microwave from the microwave inlet port 36a, the microwave can be irradiated to a circular region T at the central portion of the wafer W, because, as described above, the microwave inlet ports 36 have a parabolic surface shape and the microwave can be intensively irradiated to the region that is vertically below the microwave inlet ports 36. This is also applied to the case of irradiating the microwave from the microwave inlet port 36c although only the microwave inlet port 36a is illustrated in FIG. 7. As shown in FIG. 8, for example, if the wafer W is rotated by 360 degrees while irradiating the microwave from the microwave inlet port 36b, the microwave can be irradiated to an annular region U at the outer peripheral portion of the wafer W. In this manner, the microwave can be uniformly irradiated to the entire surface of the wafer W by rotating the wafer W while irradiating the microwave from the microwave inlet ports 36a to 36d. The microwave inlet ports 36a to 36d may be arranged such that the centers Op thereof are positioned on different circumferences having different radii or such that some of the centers Op are positioned on the same circumference.

The control unit 14 includes a storage unit 60. The control unit 14 controls the respective components of the microwave heating apparatus 10 based on a recipe stored in the storage unit 60. The instruction to the control unit 14 is executed by a dedicated control device or a CPU (not shown) for executing a program. The recipe in which processing conditions are set is previously stored in a ROM or a non-volatile memory (both not shown). The CPU reads out the conditions of the recipes from the memory and executes the recipe.

The microwave heating apparatus 1 of the present embodiment is configured as described above. Hereinafter, the heat treatment of the wafer W using the microwave heating apparatus 1 will be described.

In order to heat the wafer W, first, the gate valve 23 is opened and the wafer W is loaded into the processing chamber 10 by a transfer unit (not shown). The loaded wafer W is mounted on the supporting pins 33. Next, the gate valve 23 is closed and the processing chamber 10 is exhausted to a depressurized state by the gas exhaust unit 30. Then, a processing gas is supplied at a predetermined flow rate from the gas supply unit 12 into the processing chamber 10 and the wafer W is rotated at a predetermined speed by the driving unit 34.

Next, a voltage is applied from the power supply unit to the magnetron 42. The microwave generated by the magnetron 42 is transmitted through the waveguide 43 and irradiated to the processing space A in the processing chamber 10 through the transmission window 37 and the microwave inlet ports 36. At this time, the shaft 31 is rotated by the driving unit 34, and the wafer W mounted on the supporting pins 33 is also rotated at a predetermined speed.

Among the microwaves irradiated from the microwave inlet ports 36, the microwave Kh including a horizontal component, especially the microwave Kh moving in a perpendicular direction to the electric field surface is reflected by the annular member 70 of the corresponding microwave inlet port 36 and moved downward in a substantially vertical direction without entering the other microwave inlet ports 36. For example, the microwave Kf reflected on the surface of the wafer W is also reflected on the inner surface of the annular member 70 and moved downward in a substantially vertical direction. Accordingly, the region T at the central portion of the wafer W is intensively heated by the microwave inlet ports 36a and 36c and the region U at the outer peripheral portion of the wafer W is intensively heated by the microwave inlet ports 36b and 36d. As a result, the entire surface of the wafer W is uniformly heated.

After the heating of the wafer W using the microwave is completed, the application of the voltage from the power supply unit 41 to the magnetron 42 is stopped and the introduction of the microwave into the processing chamber 10 is stopped. In addition, the driving unit 34 is stopped, so that the rotation of the wafer W is stopped. Further, the supply of the processing gas and the cooling gas from the gas supply unit 12 is stopped. Then, the gate valve 23 is opened and the wafer W is unloaded from the processing chamber 10 to the outside. In this manner, a series of heat treatment of the wafer W is completed.

In accordance with the above embodiment, the microwave inlet ports 36 have a parabolic surface shape, so that the microwave including a horizontal component with respect to its advancing direction among the microwave irradiated from the microwave inlet port 36 is reflected on the inner surface of the annular member 70 of the corresponding microwave inlet port 36 and moved downward in a substantially vertical direction. Further, the microwave that has been irradiated downward from the microwave inlet port 36, reflected on the surface of the wafer W and then entered the corresponding microwave inlet port 36 is also reflected on the inner surface of the annular member 70 of the corresponding microwave inlet port 36 and moved downward in a substantially vertical direction. Therefore, the microwave can be intensively irradiated to the region that is vertically below the microwave inlet ports 36. In other words, the microwave irradiated from the microwave inlet ports 36 can be irradiated to a desired location at a desired intensity. Hence, in accordance with the microwave heating apparatus 1 of the present embodiment, the accuracy in heating the wafer W using the microwave can be improved and, accordingly, the surface of the wafer can be uniformly heated. Further, desired temperature distribution in the surface of the wafer W can be easily obtained by controlling the intensity of the microwave irradiated from the microwave inlet port 36.

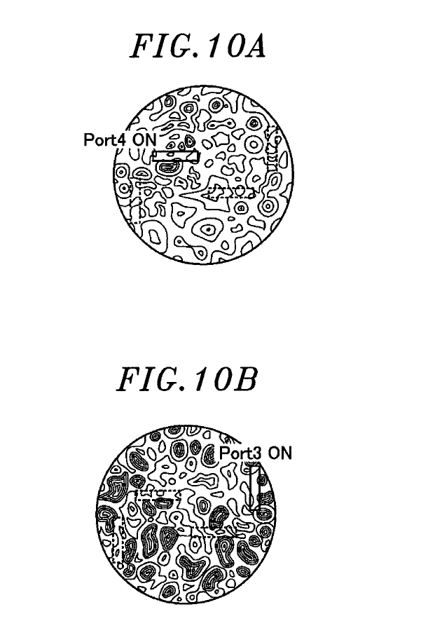

The present inventors have examined the intensity distribution of the microwave irradiated from the microwave inlet ports 36 by using the microwave heating apparatus 1 of the present embodiment. The results thereof are shown in FIGS. 9A to 9D. FIGS. 9A to 9D show the intensity distribution of the electromagnetic field in the case of irradiating the microwave from one of the microwave inlet ports 36 of the microwave heating apparatus 1 of the present embodiment while stopping the irradiation of the microwave from the other three microwave inlet ports 36. In FIGS. 9A to 9D, the intensity of the electromagnetic field is illustrated by contour lines.

FIG. 9A shows a state in which the microwave has been irradiated from “Port 4” that is one of the microwave inlet ports 36. As can be seen from FIG. 9A, the intensity of the electromagnetic field at a position corresponding to “Port 4” is higher than that at the other positions. In the same manner, FIGS. 9B to 9D show that the intensity of the electromagnetic field is higher at a position corresponding to “Port” through which the microwave has been irradiated. The above result shows that the microwave heating apparatus 1 of the present embodiment can irradiate the microwave at a desired intensity from the microwave inlet ports 36 to a desired location.

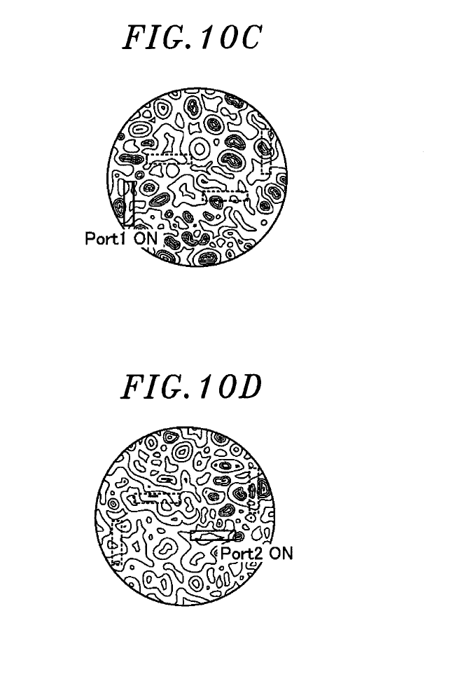

In a comparative example, the intensity of the electromagnetic field was examined by using a conventional microwave heating apparatus in which the microwave inlet ports 36 having a parabolic surface shape are not provided, i.e., in which the transmission windows 37 are directly provided at the ceiling plate 21. The results thereof are shown in FIGS. 10A to 10D. Especially, in the case of irradiating the microwave only from “Port 3” as shown in FIG. 10B, the intensity of the electromagnetic field is high across the entire surface of the wafer W. Referring to FIG. 10D, the intensity of the electromagnetic field at the position corresponding to “Port 2” through which the microwave has been irradiated is not higher than that at the other positions, which indicates that the control of the heating portion in the processing chamber 10 by the microwave is not sufficient.

In the above embodiment, the microwave heating apparatus 1 includes four microwave inlet ports 36a to 36d having the same diameter. However, the number of the microwave inlet ports 36 or the diameters of the microwave inlet ports 36 may vary without being limited to those described in the above embodiment. Particularly, since the microwave inlet ports 36 have a parabolic surface shape, the microwave irradiated from the microwave inlet ports 36 does not enter the other microwave inlet ports 36. Therefore, the transmission windows 37 do not need to be arranged so as not to interfere with one another, as shown in FIG. 5, for example. Accordingly, it is unnecessary to arrange the microwave inlet ports 36a and 36c and the microwave inlet ports 36b and 36d in a concentric circular shape, as shown in FIG. 5, for example. Hence, in the microwave heating apparatus 1 of the present embodiment, the transmission windows 37 and the microwave inlet ports 36 can be freely arranged.

In the above embodiment, the waveguide 43 has a rectangular cross section. However, the waveguide 43 may be, e.g., a coaxial waveguide. In that case, the transmission window 37 may have a circular shape instead of a rectangular shape. In any case, the microwave can be reflected and intensively irradiated in a vertically downward direction by the microwave inlet ports 36.

Further, in the above embodiment, the annular member 70 has a parabolic surface shape. However, the microwave can be reflected and irradiated in a vertically downward direction even when the cross section of the annular member 70 has, e.g., a shape whose opening area gradually becomes wider toward the wafer W, i.e., a circular truncated cone shape, instead of the parabolic surface shape. However, it is more preferable that the annular member 70 has a parabolic surface shape in order to intensively irradiate the microwave in a vertically downward direction of the microwave inlet ports 36.

In the above embodiment, the power supply unit 41 is used in common for four microwave units 40. However, the power supply unit 41 may be provided for each of the four microwave units 40, and the intensity of the microwave irradiated from the microwave inlet ports 36 may be individually controlled. In this case, the heating temperature of the central portion of the wafer W may become higher or lower than that of the outer peripheral portion of the wafer W. Therefore, it is possible to deal with various heating requirements.

While the invention has been shown and described with respect to the embodiments, it will be understood by those skilled in the art that various changes and modifications may be made without departing from the scope of the invention as defined in the following claims.

What is claimed is:

1. A microwave heating apparatus, comprising:
a processing chamber configured to accommodate a substrate;
a substrate holding unit configured to hold and rotate the substrate in the processing chamber;
a microwave generating source configured to generate a microwave; and
a plurality of microwave inlet ports formed at a surface of the processing chamber which faces the substrate in the processing chamber, each of the microwave inlet ports having an opening area that gradually becomes wider toward the substrate,
wherein the microwave generated by the microwave generating source is irradiated to the substrate in the processing chamber through the microwave inlet ports to heat the substrate.

2. The microwave heating apparatus of claim 1, wherein the microwave inlet ports have a parabolic surface shape.

3. The microwave heating apparatus of claim 1, wherein the microwave inlet ports are formed at a position corresponding to a central portion of the substrate in the processing chamber and at a position corresponding to an outer peripheral portion of the substrate in the processing chamber.

4. The microwave heating apparatus of claim 2, wherein the microwave inlet ports are formed at a position corresponding to a central portion of the substrate in the processing chamber and at a position corresponding to an outer peripheral portion of the substrate in the processing chamber.

5. The microwave heating apparatus of claim 1, wherein the microwave generating source and the microwave inlet ports are connected by a rectangular waveguide.

6. The microwave heating apparatus of claim 2, wherein the microwave generating source and the microwave inlet ports are connected by a rectangular waveguide.

7. The microwave heating apparatus of claim 3, wherein the microwave generating source and the microwave inlet ports are connected by a rectangular waveguide.

8. The microwave heating apparatus of claim 4, wherein the microwave generating source and the microwave inlet ports are connected by a rectangular waveguide.
